(19) United States
(12) Patent Application Publication
(10) Pub. No.: US 2024/0414958 A1
(43) Pub. Date: Dec. 12, 2024

(54) DISPLAY DEVICE

(71) Applicant: LG Display Co., Ltd., Seoul (KR)

(72) Inventor: JinSung KIM, Paju-si (KR)

(73) Assignee: LG Display Co., Ltd., Seoul (KR)

(21) Appl. No.: 18/399,919

(22) Filed: Dec. 29, 2023

(30) Foreign Application Priority Data
Dec. 30, 2022 (KR) 10-2022-0190031

(51) Int. Cl. H10K 59/126; H10K 59/121

(52) U.S. Cl. CPC H10K 59/126; H10K 59/1213

(57) ABSTRACT

A display device includes a light shield layer disposed on a substrate, a first buffer layer disposed on the light shield layer, a silicon layer disposed on the first buffer layer and including an undoped area and a doped area, a second buffer layer disposed on the silicon layer, and a thin film transistor disposed on the second buffer layer. The doped area is disposed at a position overlapping with the light shield layer. Accordingly, the display device can realize a wide range of grayscale representation and a fast on-off operation by adjusting the S-factor of a specific thin film transistor.

### CROSS-REFERENCE TO RELATED APPLICATION

This application claims priority to Korean Patent Application No. 10-2022-0190031, filed on Dec. 30, 2022 in the Republic of Korea, the entire contents of which is hereby expressly incorporated by reference into the present application.

### BACKGROUND

### Technical Field

Embodiments of the present disclosure relate to a display device with improved thin film transistor characteristics.

### Discussion of Related Art

Recently, with the development of multimedia, the importance of flat panel display devices is increasing. In response to this, flat panel display devices such as a liquid crystal display device, a plasma display device and an organic light emitting display device have been commercialized. Among these flat panel display devices, the organic light emitting display device is currently widely used in that it has a high response speed and high luminance and is advantageous in terms of viewing angle.

In such an organic light emitting display device, a plurality of pixels are disposed in a matrix form, and each pixel includes a light emitting element part represented by an organic light emitting layer and a pixel circuit part represented by a thin film transistor (TFT).

The pixel circuit part includes a plurality of thin film transistors such as a driving TFT which supplies a driving current to operate the light emitting element part and a switching TFT which supplies a gate signal to the driving TFT.

In a non-display area of the organic light emitting display device, a gate driving circuit unit which provides a gate signal to a pixel can be disposed.

The description provided in the background section should not be assumed to be prior art merely because it is mentioned in or associated with the background section. The background section can include information that describes one or more aspects of the subject technology.

### BRIEF SUMMARY OF THE DISCLOSURE

Since a plurality of thin film transistors disposed in the pixel circuit part in a pixel (e.g., a subpixel) and the gate driving circuit unit perform different functions, electrical characteristics corresponding thereto can be different. In order to make the electrical characteristics of the plurality of thin film transistors disposed in a pixel different, a plurality of thin film transistors made of different structures or different semiconductor materials can be formed. However, in this case, since semiconductor material layers are formed at different layers and are exposed to different etching conditions during an etching process, the reliability of an oxide semiconductor material can be degraded during a heat treatment process.

Therefore, the inventor of the present disclosure has recognized these limitations mentioned above and other limitations associated with the related art, and conducted various experiments to provide a display device capable of realizing a wide range of grayscale representation and a fast on-off operation by adjusting the S-factor of a specific thin film transistor.

Embodiments of the present disclosure are to provide a display device capable of realizing a wide range of grayscale representation and a fast on-off operation by adjusting the S-factor of a thin film transistor including an oxide semiconductor.

Embodiments of the present disclosure are to provide a display device capable of blocking or reducing light upwardly introduced into the semiconductor pattern of a thin film transistor.

Additional features and aspects of the disclosure are set forth in part in the description that follows and in part will become apparent from the description or can be learned by practice of the inventive concepts provided herein. Other features and aspects of the inventive concepts can be realized and attained by the structures pointed out in the present disclosure, or derivable therefrom, and the claims hereof as well as the appended drawings.

Embodiments of the present disclosure can provide a display device including a light shield layer disposed on a substrate; a first buffer layer disposed on the light shield layer; a silicon layer disposed on the first buffer layer, and including an undoped area and a doped area; a second buffer layer disposed on the silicon layer; and a thin film transistor disposed on the second buffer layer, wherein the doped area is disposed at a position overlapping with the light shield layer.

Embodiments of the present disclosure can provide a display device including a first light shield layer disposed on a substrate; a first buffer layer disposed on the first light shield layer; a silicon layer disposed on the first buffer layer, and including an undoped area and a doped area; a second buffer layer disposed on the silicon layer; first and second thin film transistors disposed on the second buffer layer; and a light emitting element layer electrically connected to the first thin film transistor, wherein the doped area is disposed at a position overlapping with the first light shield layer.

According to the embodiments of the present disclosure, it is possible to provide a display device capable of realizing a wide range of grayscale representation and a fast on-off operation by adjusting the S-factor of a specific thin film transistor (for example, a thin film transistor including an oxide semiconductor).

According to the embodiments of the present disclosure, it is possible to provide a display device capable of realizing a wide range of grayscale representation and a fast on-off operation by improving an S-factor by disposing a doped silicon layer under the semiconductor pattern of a specific thin film transistor.

According to the embodiments of the present disclosure, it is possible to provide a display device capable of realizing a wide range of grayscale representation and a fast on-off operation by improving an S-factor by disposing a doped silicon layer under the semiconductor pattern of a thin film transistor including an oxide semiconductor.

According to the embodiments of the present disclosure, it is possible to provide a display device capable of blocking or reducing upwardly introducing light by disposing a silicon layer under the entire surface of the semiconductor patterns of a plurality of thin film transistors.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, that can be included to provide a further understanding of the disclosure and can be incorporated in and constitute a part of the disclosure, illustrate embodiments of the disclosure and together with the description serve to explain various principles of the disclosure.

The above and other objects, features, and advantages of the present disclosure will be more clearly understood from the following detailed description, taken in conjunction with the accompanying drawings, in which:

FIG. 1 is an example of a block diagram of a display device in accordance with example embodiments of the present disclosure;

FIG. 2 is a schematic block diagram of a subpixel of the display device in accordance with example the embodiments of the present disclosure;

FIG. 3 is an example of a circuit diagram of the subpixel of the display device in accordance with the example embodiments of the present disclosure;

FIG. 4 is an example of a cross-sectional view of the display device in accordance with the example embodiments of the present disclosure;

FIG. 5A is a cross-sectional view illustrating a first thin film transistor illustrated in the display device in accordance with the example embodiments of the present disclosure of FIG. 4, whereas FIG. 5B is a cross-sectional view illustrating a first thin film transistor according to a comparison example; and

FIG. 6 is a circuit diagram illustrating a connection relationship between parasitic capacitances occurring in the first thin film transistor of FIG. 5A.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description can make the subject matter in some embodiments of the present disclosure rather unclear. The terms such as “including”, “having”, “containing”, “constituting”, “make up of”, and “formed of” used herein are generally intended to allow other components to be added unless the terms are used with the term “only”. As used herein, singular forms are intended to include plural forms unless the context clearly indicates otherwise.

The shapes, sizes, ratios, angles, numbers, and the like, which are illustrated in the drawings to describe various example embodiments of the present disclosure are merely given by way of example. Therefore, the present disclosure is not limited to the illustrations in the drawings.

Terms, such as “first”, “second”, “A”, “B”, “(A)”, or “(B)” can be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together. Any implementation described herein as an “example” is not necessarily to be construed as preferred or advantageous over other implementations.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts can be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it is typically considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “may” fully encompasses all the meanings of the term “can”.

In describing the present disclosure, a “device” can include a display device such as a liquid crystal module (LCM) and an organic light emitting display module (OLED module) which includes a display panel and a driver for driving the display panel. In addition, the device can also include a notebook computer, a television or a computer monitor which is a complete product or a final product including an LCM, an OLED module or the like, an equipment display including an automotive display or other types of vehicles, or a set electronic device or a set device (or a set apparatus) such as a smartphone or an electronic pad.

Accordingly, a device in the present disclosure can include a display device such as an LCM, an OLED module or the like, and an application product or a set device which is an end consumer device, including the LCM, the OLED module or the like.

In embodiments of the present disclosure, an LCM or an OLED module configured by a display panel, a driving unit and so forth can be expressed as a display device, and an electronic device as a complete product including an LCM or an OLED module can be differently expressed as a set device. For example, the display device can include a display panel such as an LCD or an OLED and a source PCB as a controller for driving the display panel. The set device can further include a set PCB as a set controller which is electrically connected to the source PCB to drive the entire set device.

As a display panel used in embodiments of the present disclosure, all types of display panels such as a liquid crystal display panel, an organic light emitting diode (OLED) display panel and an electroluminescent display panel can be used, but the embodiments of the present disclosure are not limited thereto. For example, the display panel can be a display panel which can generate sound by being vibrated by a vibration device in accordance with embodiments of the present disclosure. A display panel applied to a display device in accordance with embodiments of the present disclosure is not limited in its shape or size.

Features of various embodiments of the present disclosure can be combined partially or totally, technically various interactions and operations are possible, and the respective embodiments can be practiced individually or in combination.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Hereinafter, various embodiments of the present disclosure will be described in detail with reference to the accompanying drawings. All the components of each light emitting display device according to all embodiments of the present disclosure are operatively coupled and configured.

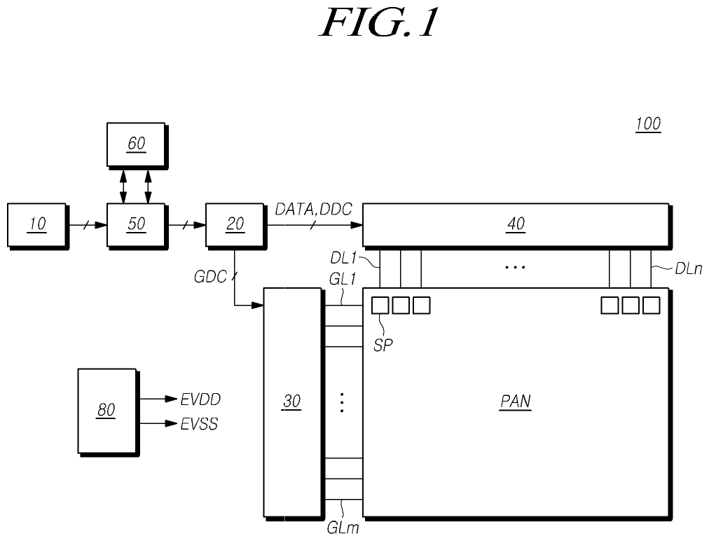

FIG. 1 is a block diagram illustrating a light emitting display device in accordance with embodiments of the present disclosure.

Referring to FIG. 1, a display device 100 in accordance with embodiments of the present disclosure includes a display panel PAN, an image processing unit 10, a degradation compensation unit 50, a memory 60, a timing controller 20, a data driving unit 40, a power supply unit 80 and a gate driving unit 30 which transfer signals to the display panel PAN. The display panel PAN includes a plurality of subpixels SP, which can be arranged in a matrix configuration or other suitable configuration.

The image processing unit 10 outputs driving signals for driving various components together with image data supplied from the outside. For example, the driving signals outputted from the image processing unit 10 can include a data enable signal, a vertical synchronization signal, a horizontal synchronization signal, a clock signal, etc. The data enable signal indicates when the image data is valid and ready for processing, while the vertical and horizontal synchronization signals are used to synchronize the timing of the image data in relation to the display panel's rows and columns. The clock signal, on the other hand, serves as a reference for timing the transmission and processing of the image data within the system.

The degradation compensation unit 50 can calculate a degradation compensation gain value of a subpixel SP of the display panel PAN on the basis of a sensing voltage (Vsen) supplied from the data driving unit 40. The degradation compensation unit 50 can calculate a dimming weight value on the basis of the calculated degradation compensation gain value. Thereafter, the degradation compensation unit 50 can modulate input image data (Idata) of each subpixel of a current frame by the calculated degradation compensation gain value and dimming weight value, and then, can supply modulated image data (Mdata) to the timing controller 20. For example, the degradation compensation unit 50 plays a role in maintaining the image quality of the display panel by actively compensating for any degradation in the performance of individual subpixels. By calculating degradation compensation gain values and dimming weight values, and modulating the input image data accordingly, the degradation compensation unit 50 can ensure that the display panel continues to provide accurate and consistent image rendering despite any potential wear and tear on the subpixels.

The timing controller 20 can receive driving signals together with image data modulated in the degradation compensation unit 50. On the basis of the driving signals inputted from the image processing unit 10, the timing controller 20 can generate and output a gate timing control signal GDC for controlling the operation timing of the gate driving unit 30 and a data timing control signal DDC for controlling the operation timing of the data driving unit 40.

The timing controller 20 can obtain at least one sensing voltage (Vsen) from each subpixel SP by controlling operation timings of the gate driving unit 30 and the data driving unit 40, and can supply the obtained sensing voltage (Vsen) to the degradation compensation unit 50.

The gate driving unit 30 can output a scan signal to the display panel PAN in response to the gate timing control signal GDC supplied from the timing controller 20. The gate driving unit 30 can be disposed on one side or both sides of the display panel 100, and the gate driving unit 30 can output the scan signal through a plurality of gate lines GL1 to GLm where m can be a positive integer. The gate driving unit 30 can be formed in the type of an integrated circuit (IC), but is not limited thereto. The gate driving unit 30 can be formed in a gate-in-panel (GIP) structure which is formed by directly stacking thin film transistors on the substrate of the display device 100 or a tape automated bonding (TAB) method. The GIP structure can include a plurality of circuits such as a shift register, a level shifter and so forth. The gate driving unit 30 sequentially outputs scan signals to the plurality of gate lines GL1 to GLm under control of timing controller 20, thereby controlling the driving timing of the plurality of subpixels. The gate driving unit 30 can sequentially supply the scan signals to the gate lines GL1 to GLm by shifting the gate signals using the shift register.

The data driving unit 40 can output a data voltage to the display panel PAN in response to the data timing control signal DDC inputted from the timing controller 20. The data driving unit 40 can sample and latch a data signal DATA of a digital type supplied from the timing controller 20, and can convert the data signal DATA into a data voltage of an analog type on the basis of a gamma voltage. The data driving unit 40 can output the data voltage through a plurality of data lines DLI to DLn where n can be a positive integer. Although the data driving unit 40 is illustrated in FIG. 1 as being disposed on one side of the display panel PAN in a single shape, the number and position of the data driver 400 is not limited thereto.

The data driving unit 40 can supply the sensing voltage (Vsen) inputted through a sensing voltage readout line from the display panel PAN, to the degradation compensation unit 50. The data driving unit 40 can be mounted onto the display panel PAN in the form of an integrated circuit (IC) or can be formed by being directly stacked on the display panel PAN together with various patterns, but is not limited thereto.

In the memory 60, not only a lookup table for a degradation compensation gain can be stored, but also a degradation compensation time point of a light emitting element layer of the subpixel SP can be stored. The degradation compensation time point of the light emitting element layer can be the number of driving times or the driving time of a light emitting display device.

The power supply unit 80 can output and supply gate-low voltages VGL, gate-high voltages VGH, a high potential driving voltage EVDD and a low potential driving voltage EVSS, a reference voltage Vref, an initialization voltage Vinit and the like to the display panel PAN. The high potential driving voltage EVDD and the low potential driving voltage EVSS can be supplied to the display panel PAN through power lines. A voltage outputted from the power supply unit 80 can also be outputted to the gate driving unit 30 or the data driving unit 40 to be used in driving the gate driving unit 30 or the data driving unit 40.

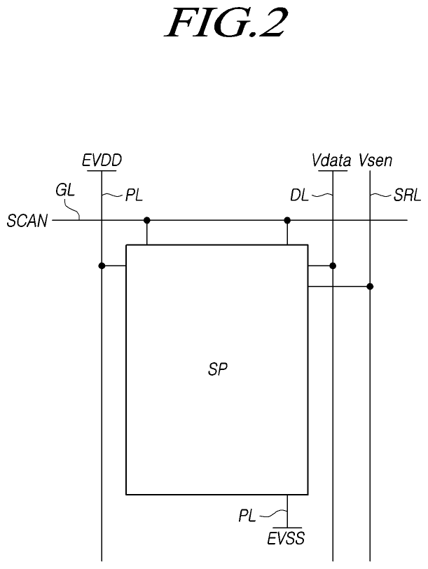

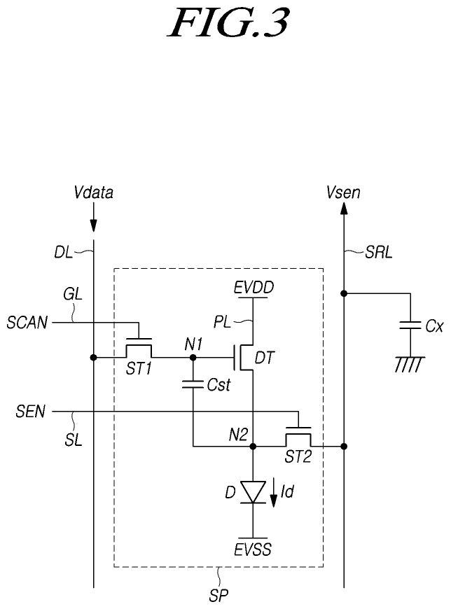

FIGS. 2 and 3 are diagrams for explaining the driving of the display device in accordance with the example embodiments of the present disclosure.

Particularly, FIG. 2 is a schematic block diagram of a subpixel of the display device in accordance with the example embodiments of the present disclosure. FIG. 3 is a circuit diagram of the subpixel of the display device in accordance with the example embodiments of the present disclosure. The subpixel configurations of FIGS. 2 and 3 can be the configuration of each subpixel of the display device in FIG. 1 or in other figures of the present disclosure.

Although FIG. 3 illustrates and describes a display device of a 3TIC structure including three thin film transistors and one storage capacitor, the display device of the present disclosure is not limited to such a structure, and can be applied to various structures such as 4TIC, 5TIC, 6TIC, 7TIC, 8TIC, 4T2C, 5T2C, 6T2C, 7T2C and 8T2C.

Referring to FIGS. 2 and 3, the display device 100 in accordance with the example embodiments of the present disclosure includes a gate line GL, a data line DL, a power line PL and a sensing line SL. Each subpixel SP includes a first switching thin film transistor ST1, a second switching thin film transistor ST2, a driving thin film transistor DT, an organic light emitting element D and a storage capacitor Cst.

The organic light emitting element D includes an anode electrode which is connected to a second node N2, a cathode electrode which is connected to an input terminal of the low potential driving voltage EVSS, and a light emitting element layer which is positioned between the anode electrode and the cathode electrode.

The driving thin film transistor DT can control a current Id flowing through the organic light emitting element D according to a gate-source voltage Vgs. The driving thin film transistor DT can include a gate electrode which is connected to a first node N1, a drain electrode which is connected to the power line PL to be provided with the high potential driving voltage EVDD, and a source electrode which is connected to the second node N2.

The storage capacitor Cst is connected between the first node N1 and the second node N2. The storage capacitor Cst allows a constant voltage to be maintained during one frame.

When driving the display panel PAN, the first switching thin film transistor ST1 applies a data voltage Vdata charged to a data line DL to the first node N1 in response to a gate signal SCAN to turn on the driving thin film transistor DT. The first switching thin film transistor ST1 can include a gate electrode which is connected to a gate line GL to receive the gate signal SCAN, a drain electrode which is connected to the data line DL to receive the data voltage Vdata and a source electrode which is connected to first node N1.

The second switching thin film transistor ST2 switches a current between the second node N2 and a sensing voltage readout line SRL in response to a sensing signal SEN to store the voltage of the second node N2 (for example, the source voltage of the driving thin film transistor DT) in a sensing capacitor Cx of the sensing voltage readout line SRL. When driving the display panel PAN, the second switching thin film transistor ST2 switches a current between the second node N2 and the sensing voltage readout line SRL in response to the sensing signal SEN to reset the source voltage of the driving thin film transistor DT to an initialization voltage Vpre. A gate electrode of the second switching thin film transistor ST2 is connected to the sensing line SL, a drain electrode of the second switching thin film transistor ST2 is connected to the second node N2, and a source electrode of the second switching thin film transistor ST2 is connected to the sensing voltage readout line SRL.

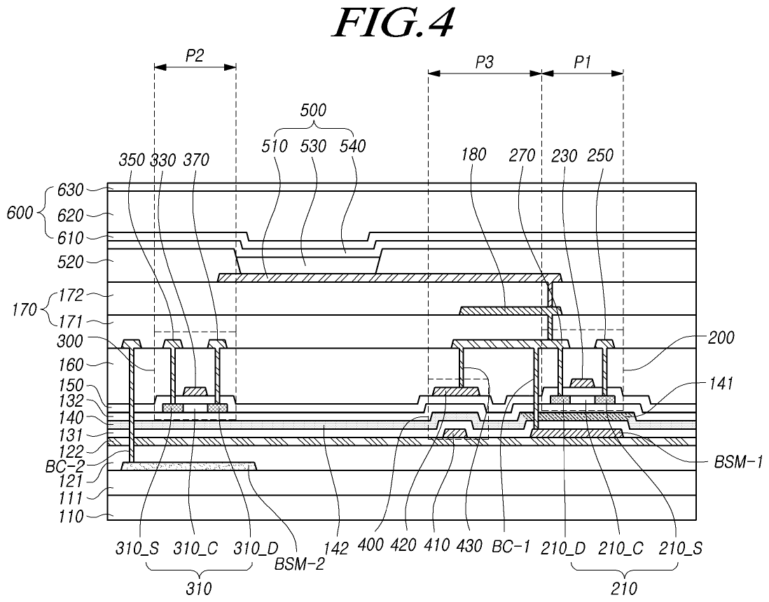

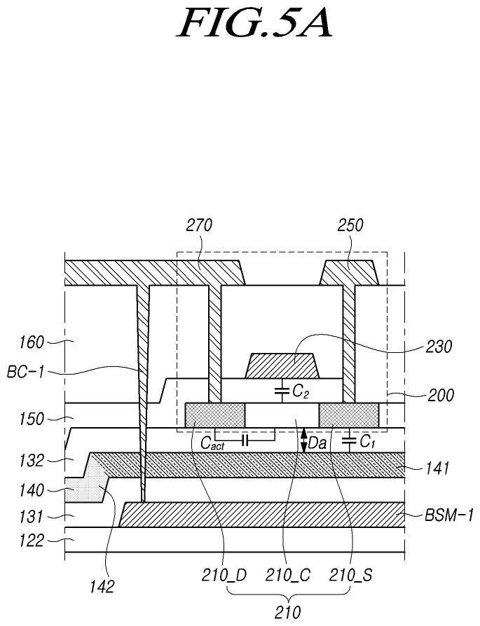

FIG. 4 is a cross-sectional view of the display device in accordance with the example embodiments of the present disclosure.

Referring to FIG. 4, the display device 100 in accordance with the example embodiments of the present disclosure can include a substrate 110, a first thin film transistor 200, a second thin film transistor 300 and a capacitor 400.

On the substrate 110, the first thin film transistor 200 can be disposed in a first area P1, the second thin film transistor 300 can be disposed in a second area P2, and the capacitor 400 can be disposed in a third area P3.

The first area P1, the second area P2 and the third area P3 can be different areas on the substrate 110. The first area P1, the second area P2 and the third area P3 can be disposed in a display area or a non-display area. For example, the first thin film transistor 200 can be disposed in the display area, and the second thin film transistor 300 can be disposed in the non-display area, but the present disclosure is not limited thereto.

Alternatively, the first area P1, the second area P2 and the third area P3 can be disposed in the display area. For example, the first thin film transistor 200, the second thin film transistor 300 and the capacitor 400 can be disposed in a single subpixel SP. The first thin film transistor 200 can be referred to as a driving thin film transistor. The second thin film transistor 300 can be referred to as a switching thin film transistor.

The capacitor 400 can store a data voltage applied through a data line, for a certain period of time, and then, can provide the data voltage to a light emitting element layer 500.

The substrate 110 can support various components of the display device 100. The substrate 110 can be made of a plastic material having flexibility. For example, the substrate 110 can be formed of at least one of polyimide, polyethersulfone, polyethylene terephthalate and polycarbonate, but is not limited thereto.

When the substrate 110 is made of a plastic material, the manufacturing process of a display device can proceed in a state in which a support substrate made of glass is disposed under the substrate 110, and after the manufacturing process of the display device is completed, the support substrate can be released. Further, after the support substrate is released, a back plate (or a plate) for supporting the substrate 110 can be disposed under the substrate 110.

When the substrate 110 is made of a plastic material, moisture can penetrate into the substrate 110, and the penetration of moisture can proceed up to a thin film transistor or a light emitting element layer, degrading the performance of the display device. The display device in accordance with the example embodiments of the present disclosure can include two substrates made of a plastic material so as to prevent or reduce the performance of the display device from degrading due to moisture penetration. In addition, by forming an inorganic film between the two substrates, it is possible to block or reduce moisture from penetrating into a substrate, thereby improving the performance and reliability of a product. The inorganic film can be formed of a single layer of silicon nitride (SiNx) or silicon oxide (SiOx) or a multi-layer thereof, but is not limited thereto.

The substrate 110 can be referred to as a concept including elements and functional layers formed on a substrate, for example, a switching thin film transistor, a driving thin film transistor connected to the switching thin film transistor, a light emitting element connected to the driving thin film transistor and a protective layer, but is not limited thereto.

A multi-buffer layer 111 can be disposed on the entire surface of the substrate 110. The multi-buffer layer 111 can perform the function of enhancing adhesion between layers formed on the multi-buffer layer and the substrate and blocking an alkaline components or the like leaking out of the substrate 110. In addition, the multi-buffer layer 111 can delay diffusion of moisture or oxygen penetrated into the substrate 110.

The multi-buffer layer 111 can be made of a single layer of silicon nitride (SiNx) or silicon oxide (SiOx) or a multi-layer thereof. When the multi-buffer layer 111 is made of a multi-layer, silicon oxide (SiOx) and silicon nitride (SiNx) can be alternately formed.

The multi-buffer layer 111 can be omitted on the basis of the type and material of the substrate 110, the structure and type of a thin film transistor, and so on.

On the multi-buffer layer 111, a second light shield layer BSM-2 can be disposed in the second area P2.

The second light shield layer BSM-2 can be disposed below a second semiconductor pattern 310 to be described later, which is positioned in the second area P2, and can be disposed to overlap with the second semiconductor pattern 310.

The second light shield layer BSM-2 can have an area equal to or larger than the area of the second semiconductor pattern 310.

A light shield layer can prevent or reduce the malfunction of a semiconductor pattern when light incident from the outside of a display device is irradiated to the semiconductor pattern.

The light shield layer can prevent or reduce a l caused due to an inflow of charges from a substrate. For example, when a voltage is applied to the gate electrode of a thin film transistor for a long time, the charges of the substrate can flow into the channel area of a semiconductor pattern of a thin film transistor due to an electric field generated in the thin film transistor, thereby changing the amount of charges of the corresponding channel area (a back channel phenomenon). Charges can be either holes or charges depending on the polarity of the electric field. The substrate can change the current of the thin film transistor to cause a change in the threshold voltage of the thin film transistor. This can cause a change in the luminance of a pixel and an afterimage. Accordingly, by disposing a light shield layer between the substrate and the semiconductor pattern to block or reduce unwanted charge flow from the substrate into the thin film transistor, it is possible to prevent or reduce the threshold voltage (Vth) of the thin film transistor from being changed and prevent or reduce an afterimage. Further, it is possible to secure or increase the stability of the thin film transistor during driving and improve display quality.

The second light shield layer BSM-2 can be disposed using an opaque conductive material to block or reduce light incident from the outside of the display device. For example, the second light shield layer BSM-2 can be formed as a single layer or a multi-layer made of any one of molybdenum (Mo), copper (Cu), titanium (Ti), aluminum (Al), chromium (Cr), gold (Au), nickel (Ni), neodymium (Nd) and tungsten (W) or an alloy thereof, but is not limited thereto.

The second light shield layer BSM-2 can include titanium (Ti) that can stably bond with hydrogen. It is possible to block or reduce, by the second light shield layer BSM-2, hydrogen remaining between a substrate and an insulating layer from penetrating into a semiconductor pattern by a semiconductor pattern forming process. Accordingly, since the semiconductor pattern is prevented or alleviated from becoming conductive by the second light shield layer BSM-2, reliability on operational characteristics of the thin film transistor of the display device in accordance with the example embodiments of the present disclosure can be improved.

The second light shield layer BSM-2 can be electrically connected to a second connection electrode BC-2.

The second connection electrode BC-2 can be provided with a constant voltage from the outside. Therefore, since the second light shield layer BSM-2 can be maintained as the same voltage as the second connection electrode BC-2, a change in the characteristics of elements disposed around the second light shield layer BSM-2 can be reduced. That is to say, since the second light shield layer BSM-2 is less affected by an external voltage, a change in the threshold voltage (Vth) of the second thin film transistor 300 due to a back channel phenomenon can be prevented or reduced.

A first insulating layer 121 can be disposed on the second light shield layer BSM-2. The first insulating layer 121 can be formed of an insulating inorganic material such as silicon nitride (SiNx) or silicon oxide (SiOx), and besides, can also be formed of an insulating organic material.

A first interlayer insulating layer 122 can be disposed on the first insulating layer 121. The first interlayer insulating layer 122 can be formed of an insulating material such as silicon nitride (SiNx) or silicon oxide (SiOx), and besides, can also be formed of an insulating organic material.

The first interlayer insulating layer 122 can be made of a single layer or a multi-layer of silicon nitride (SiNx) or silicon oxide (SiOx), but is not limited thereto.

On the first interlayer insulating layer 122, a first light shield layer BSM-1 can be disposed in the first area P1 and a first capacitor electrode 410 of the capacitor 400 can be disposed in the third area P3.

The first light shield layer BSM-1 and the first capacitor electrode 410 can be formed of the same material and by the same process.

The first light shield layer BSM-1 can be disposed below a first semiconductor pattern 210 to be described later, which is positioned in the first area P1, and can be disposed to overlap with the first semiconductor pattern 210.

The first light shield layer BSM-1 can have an area equal to or larger than the area of the first semiconductor pattern 210.

As described above, a light shield layer can prevent or reduce the malfunction of a semiconductor pattern when light incident from the outside of a display device is irradiated to the semiconductor pattern.

The first light shield layer BSM-1 can be disposed using an opaque conductive material to block or reduce light incident from the outside of the display device. For example, the first light shield layer BSM-1 can be formed as a single layer or a multi-layer made of any one of molybdenum (Mo), copper (Cu), titanium (Ti), aluminum (Al), chromium (Cr), gold (Au), nickel (Ni), neodymium (Nd) and tungsten (W) or an alloy thereof, but are not limited thereto.

The first light shield layer BSM-1 can include titanium (Ti) that can stably bond with hydrogen. It is possible to block or reduce, by the first light shield layer BSM-1, hydrogen remaining between a substrate and an insulating layer from penetrating into a semiconductor pattern by a semiconductor pattern forming process. Accordingly, since the semiconductor pattern is prevented or alleviated from becoming conductive by the first light shield layer BSM-1, reliability on operational characteristics of the thin film transistor of the display device in accordance with the example embodiments of the present disclosure can be improved.

The first capacitor electrode 410 can be formed as a single layer or a multi-layer made of any one of molybdenum (Mo), copper (Cu), titanium (Ti), aluminum (Al), chromium (Cr), gold (Au), nickel (Ni), neodymium (Nd) and tungsten (W) or an alloy thereof, but is not limited thereto.

The first light shield layer BSM-1 can be electrically connected to a first drain electrode 270 through a first connection electrode BC-1.

The first connection electrode BC-1 can be formed in the holes of a first buffer layer 131, a doped area 141 of a silicon layer 140, a second buffer layer 132, a second insulating layer 150 and a second interlayer insulating layer 160, and can electrically connect the first drain electrode 270, the doped area 141 of the silicon layer 140 and the first light shield layer BSM-1.

For example, when driving the display device, since the first light shield layer BSM-1 can be maintained as the same voltage as the first drain electrode 270, a change in the characteristics of elements disposed around the first light shield layer BSM-1 can be reduced. That is to say, since the first light shield layer BSM-1 is less affected by an external voltage, a change in the threshold voltage (Vth) of the first thin film transistor 200 due to a back channel phenomenon can be prevented or reduced.

The first connection electrode BC-1 can be formed of the same material as a first source electrode 250, the first drain electrode 270, a second source electrode 350, a second drain electrode 370 and a fourth connection electrode 430. The first connection electrode BC-1 can be formed as a single layer or a multi-layer made of any one of molybdenum (Mo), copper (Cu), titanium (Ti), aluminum (Al), chromium (Cr), gold (Au), nickel (Ni) and neodymium (Nd) or an alloy thereof, but is not limited thereto.

The first buffer layer 131 can be disposed on the first light shield layer BSM-1 and the first capacitor electrode 410.

The first buffer layer 131 can be formed of a single layer of silicon nitride (SiNx) or silicon oxide (SiOx) or a multi-layer thereof. When the first buffer layer 131 is formed of a multi-layer, silicon oxide (SiOx) and silicon nitride (SiNx) can be alternately formed.

The silicon layer 140 can be disposed on the entire surface of the first buffer layer 131. The silicon layer 140 can include the doped area 141 and an undoped area 142. The doped area 141 can be disposed over the first light shield layer BSM-1 and can be disposed to overlap with the first light shield layer BSM-1. The undoped area 142 can be disposed in an area other than the doped area 141.

The doped area 141 can have an area equal to or larger than the area of the first light shield layer BSM-1.

The silicon layer 140 can include any one selected from the group including monocrystalline silicon, polycrystalline silicon, and amorphous silicon.

The doped area 141 can be doped with an n-type impurity or a p-type impurity. The doped area 141 as the doped area of the silicon layer 140 can have high conductivity.

For example, the doped area 141 of the silicon layer 140 can be doped with an n-type impurity such as phosphorus (P), arsenic (As), antimony (Sb) or bismuth (Bi). Alternatively, the doped area 141 of the silicon layer 140 can be doped with a p-type impurity such as boron (B), aluminum (Al), indium (In) or gallium (Ga).

Since the silicon layer 140 is disposed on the entire surface of the first buffer layer 131, the silicon layer 140 can serve as a light shield. In other words, by disposing the silicon layer 140 below the entire surfaces of semiconductor patterns of a plurality of thin film transistors, it is possible to block or reduce upwardly introducing light introduced into the semiconductor patterns from a lower part.

The doped area 141 can be electrically connected to the first drain electrode 270 through the first connection electrode BC-1.

The second buffer layer 132 can be disposed on the silicon layer 140. The second buffer layer 132 can be formed of a single layer of silicon nitride (SiNx) or silicon oxide (SiOx) or a multi-layer thereof. When the second buffer layer 132 is formed of a multi-layer, silicon oxide (SiOx) and silicon nitride (SiNx) can be alternately formed.

On the second buffer layer 132, the first semiconductor pattern 210 can be disposed in the first area P1 and the second semiconductor pattern 310 can be disposed in the second area P2.

The first semiconductor pattern 210 can be made of an oxide semiconductor. When a polycrystalline semiconductor pattern which is advantageous for a high-speed operation is used as a semiconductor pattern of a driving thin film transistor, a problem can arise in that leakage current occurs in an off state, resulting in large power consumption. Therefore, oxide that is advantageous for blocking or reducing leakage current can be formed as a semiconductor pattern.

Since an oxide semiconductor material has a larger bandgap than a silicon semiconductor material, electrons cannot cross the bandgap in an off state, and thus, off-current is low.

The off-current is the leakage current between the source electrode and the drain electrode of a TFT in the off state of the TFT. When a driving thin film transistor is made of an oxide semiconductor material which has low off-current, since the effect of blocking or reducing leakage current is excellent even when an off state is long, it is possible to minimize or reduce a change in luminance of a subpixel during low-speed driving. In addition, since the leakage current is low in the off state, power consumption can be reduced.

However, the thin film transistor using an oxide semiconductor pattern as an active layer is likely to have defects in a low grayscale region where precise current control is required because a variation value in current for a unit variation value in voltage is large due to the nature of the material of the oxide semiconductor. Therefore, example embodiments of the present disclosure can provide a display device including a thin film transistor in which the change value of current in the active layer is relatively insensitive with respect to the change value of voltage applied to the gate electrode.

The first semiconductor pattern 210 can be made of metal oxide. For example, the first semiconductor pattern 210 can be made of any one of indium-gallium-zinc-oxide (IGZO), indium-zinc-oxide (IZO), indium-gallium-tin-oxide (IGTO) and indium-gallium-oxide (IGO), but is not limited thereto.

Conductive characteristics of the metal oxide material can be improved by a doping process in which impurities are implanted.

The first semiconductor pattern 210, can include a first channel area 210_C, of which a doping process is not performed, forming a channel through which electrons or holes move in the first semiconductor pattern 210 when the first thin film transistor 200 is driven. Further, the first channel area 210_C can be disposed such that it overlaps a first gate electrode 230.

A first source area 210_S and a first drain area 210_D which become conductive by a doping process can be included on both sides of the first channel area 210_C. The first source area 210_S can mean a portion of the first semiconductor pattern 210 which is connected to the first source electrode 250, and the first drain area 210_D can mean a portion of the first semiconductor pattern 210 which is connected to the first drain electrode 270.

The first source area 210_S and the first drain area 210_D can be formed by a doping process in which one of group III elements such as boron is implanted into a metal oxide material.

The second semiconductor pattern 310 can be made of a polycrystalline semiconductor. For example, a polycrystalline semiconductor can be made of low temperature polysilicon (LTPS) having high mobility. When the second semiconductor pattern 310 is made of a polycrystalline semiconductor, power consumption is low and reliability is excellent.

Alternatively, the second semiconductor pattern 310 can be made of amorphous silicon (a-Si), or can be made of various organic semiconductor materials such as pentacene. Alternatively, the second semiconductor pattern 310 can be made of oxide, but is not limited thereto.

An amorphous silicon (a-Si) material can be deposited on the second buffer layer 132, polysilicon can be formed in such a way to perform a dehydrogenation process, a crystallization process, an activation process and a hydrogenation process, and the second semiconductor patterns 310 can be formed by patterning the polysilicon.

The second semiconductor pattern 310, can include a second channel area 310_C, of which a doping process is not performed, forming a channel through which electrons or holes move in the second thin film transistor 300 is driven. Further, the second channel area 310_C can be disposed such that it overlaps a second gate electrode 330.

A second source area 310_S and a second drain area 310_D which become conductive by a doping process can be included on both sides of the second channel area 310_C. The second source area 310_S can mean a portion of the second semiconductor pattern 310 which is connected to the second source electrode 350, and the second drain area 310_D can mean a portion of the second semiconductor pattern 310 which is connected to the second drain electrode 370.

The second source area 310_S and the second drain area 310_D can be formed by doping ions into a polycrystalline silicon material.

The second source area 310_S and the second drain area 310_D are areas which become conductive by implanting one of group III or V elements into a polycrystalline semiconductor material. For example, the second source area 310_S and the second drain area 310_D can include phosphorus (P) or boron (B).

When the semiconductor pattern of a thin film transistor is made of a polycrystalline semiconductor material, characteristics of the polycrystalline semiconductor material degrade when vacancies exist. Therefore, through a heat treatment process, hydrogen included in an insulating layer such as silicon nitride (SiNx) can diffuse into the polycrystalline semiconductor material and fill the vacancies existing in the polycrystalline semiconductor material, thereby improving the element characteristics of the semiconductor pattern. For example, an insulating layer such as silicon nitride (SiNx) includes a large amount of hydrogen particles during a manufacturing process. By performing heat treatment, hydrogen included in an insulating layer such as silicon nitride (SiNx) can diffuse into the second semiconductor pattern 310 made of a polycrystalline semiconductor pattern by subsequent heat treatment and fill vacancies existing in the polycrystalline semiconductor material, thereby improving the element characteristics of the second semiconductor pattern 310. Accordingly, the second semiconductor pattern 310 can be stabilized.

The second insulating layer 150 can be disposed on the second buffer layer 132, the first semiconductor pattern 210 and the second semiconductor pattern 310.

The second insulating layer 150 can be disposed between the first semiconductor pattern 210 and the first gate electrode 230 in the first area P1. The second insulating layer 150 can insulate the first semiconductor pattern 210 and the first gate electrode 230.

The second insulating layer 150 can be disposed between the second semiconductor pattern 310 and the second gate electrode 330 in the second area P2. The second insulating layer 150 can insulate the second semiconductor pattern 310 and the second gate electrode 330.

In addition, the second insulating layer 150 can be disposed between the first capacitor electrode 410 and a second capacitor electrode 420 in the third area P3.

The second insulating layer 150 can be formed of an insulating material such as silicon nitride (SiNx) or silicon oxide (SiOx), and besides, can also be formed of an insulating organic material.

The second insulating layer 150 can include a hole to electrically connect each of the first source electrode 250 and the first drain electrode 270 to the first semiconductor pattern 210. Further, the second insulating layer 150 can include a hole to electrically connect each of the second source electrode 350 and the second drain electrode 370 to the second semiconductor pattern 310.

On the second insulating layer 150, the first gate electrode 230 can be disposed in the first area P1, the second gate electrode 330 can be disposed in the second area P2, and the second capacitor electrode 420 can be disposed in the third area P3.

The first gate electrode 230 can be disposed to overlap with the first semiconductor pattern 210, the second gate electrode 330 can be disposed to overlap with the second semiconductor pattern 310, and the second capacitor electrode 420 can be disposed to overlap with the first capacitor electrode 410.

The capacitor 400 can include two electrodes corresponding to each other and a dielectric disposed therebetween. The capacitor 400 can include the first capacitor electrode 410 and the second capacitor electrode 420. At least two insulating layers can be interposed between the first capacitor electrode 410 and the second capacitor electrode 420. For example, the first buffer layer 131, the undoped area 142 of the silicon layer 140, the second buffer layer 132 and the second insulating layer 150 can be disposed between the first capacitor electrode 410 and the second capacitor electrode 420.

The second capacitor electrode 420 can be electrically connected to the light emitting element layer 500 through the first drain electrode 270 or a third connection electrode 180.

The second capacitor electrode 420 of the capacitor 400 can be electrically connected to the first drain electrode 270. For example, the second capacitor electrode 420 can be electrically connected to the first drain electrode 270 through the fourth connection electrode 430. In addition, the second capacitor electrode 420 can be electrically connected to the first semiconductor pattern 210 (for example, the first drain area 210_D) through the first drain electrode 270. However, the present disclosure is not limited thereto. For example, the second capacitor electrode 420 can be electrically connected to the first source electrode 250 instead of the first drain electrode 270, and then electrically connected to the first semiconductor pattern 210 (for example, the first source area 210_S) through the first source electrode 250. Accordingly, the drain electrode described herein can be a source electrode, and vice versa.

When the display device is driven by signals applied through signal lines, a distortion in the voltage of a thin film transistor can occur. In this consideration, the capacitor 400 can be connected to the first thin film transistor 200. Accordingly, the capacitor 400 stores a data voltage applied through a data line, for a certain period of time, thereby preventing or reducing the distortion of a voltage by signal lines during driving and enabling a driving circuit to operate stably.

The first gate electrode 230, the second gate electrode 330 and the second capacitor electrode 420 can be formed as a single layer or a multi-layer made of any one of molybdenum (Mo), copper (Cu), titanium (Ti), aluminum (Al), chromium (Cr), gold (Au), nickel (Ni), neodymium (Nd) and tungsten (W) or an alloy thereof, but are not limited thereto.

By simultaneously forming an electrode constituting the capacitor 400 when disposing an electrode or metal material constituting different types of thin film transistors, the number of processes can decrease and the manufacturing cost can be reduced. For example, when disposing the first light shield layer BSM-1 in the first area P1, the first capacitor electrode 410 can be simultaneously disposed in the third area P3. In addition, when disposing the first gate electrode 230 of the first thin film transistor 200 in the first area P1 and the second gate electrode 330 of the second thin film transistor 300 in the second area P2, the second capacitor electrode 420 can be simultaneously disposed in the third area P3. Accordingly, since an electrode constituting the capacitor 400 does not need to be formed through a separate process, the number of processes can decrease and the manufacturing cost can be reduced.

The second interlayer insulating layer 160 can be disposed on the second insulating layer 150, the first gate electrode 230, the second gate electrode 330 and the second capacitor electrode 420. The second interlayer insulating layer 160 can be formed of an insulating material such as silicon nitride (SiNx) or silicon oxide (SiOx), and can also be formed of an insulating organic material.

The second interlayer insulating layer 160 can include a hole to electrically connect each of the first source electrode 250 and the first drain electrode 270 to the first semiconductor pattern 210.

The second interlayer insulating layer 160 can include a hole to electrically connect each of the second source electrode 350 and the second drain electrode 370 to the second semiconductor pattern 310.

The second interlayer insulating layer 160 can include a hole to electrically connect the first drain electrode 270 and the second capacitor electrode 420.

On the second interlayer insulating layer 160, the first source electrode 250 and the first drain electrode 270 can be disposed in the first area P1, and the second source electrode 350 and the second drain electrode 370 can be disposed in the second area P2.

The first source electrode 250 and the first drain electrode 270 disposed in the first area P1 are electrically connected to the first semiconductor pattern 210 through holes in the second insulating layer 150 and the second interlayer insulating layer 160.

The second source electrode 350 and the second drain electrode 370 disposed in the second area P2 are electrically connected to the second semiconductor pattern 310 through holes in the second insulating layer 150 and the second interlayer insulating layer 160.

The fourth connection electrode 430 can be disposed in the third area P3. The fourth connection electrode 430 can be formed in a hole of the second interlayer insulating layer 160, and can electrically connect the second capacitor electrode 420 and the first drain electrode 270.

The first source electrode 250, the first drain electrode 270, the second source electrode 350, the second drain electrode 370 and the fourth connection electrode 430 can be formed as a single layer or a multi-layer made of any one of molybdenum (Mo), copper (Cu), titanium (Ti), aluminum (Al), chromium (Cr), gold (Au), nickel (Ni) and neodymium (Nd) or an alloy thereof, but are not limited thereto. For example, the first source electrode 250, the first drain electrode 270, the second source electrode 350, the second drain electrode 370 and the fourth connection electrode 430 can be made of a three-layered structure of titanium (Ti)/aluminum (Al)/titanium (Ti) as conductive metal materials, but are not limited thereto.

A planarization layer 170 can be disposed on the first source electrode 250, the first drain electrode 270, the second source electrode 350 and the second drain electrode 370.

The planarization layer 170 can be disposed to cover the first thin film transistor 200 and the second thin film transistor 300. The planarization layer 170 can protect thin film transistors disposed thereunder and alleviate or planarize steps caused by various patterns.

The planarization layer 170 can be formed of at least one material among organic insulating materials such as benzocyclobutene (BCB), acrylic resin, epoxy resin, phenolic resin, polyamide resin and polyimide resin, but is not limited thereto. The planarization layer 170 can be disposed as a single layer, but can be disposed as a plurality of layers of two or more layers in consideration of the layout of electrodes.

As the display device 100 evolves to a high resolution, the number of various signal lines increases. Therefore, since it is difficult to dispose all the signal lines in one layer while securing a minimum gap, an additional layer is formed. This additional layer can provide a margin for signal line layout, which makes it easier to design the layout of signal lines/electrodes. In addition, when a dielectric material is used as a planarization layer composed of multiple layers, the planarization layer can be utilized as a use for forming capacitance between metal layers.

When the planarization layer 170 is disposed as two layers, the planarization layer 170 can include a first planarization layer 171 and a second planarization layer 172.

The third connection electrode 180 can be disposed between the first planarization layer 171 and the second planarization layer 172.

By forming a hole in the first planarization layer 171 and disposing the third connection electrode 180 in the hole, the first thin film transistor 200 and the light emitting element layer 500 can be electrically connected through the third connection electrode 180.

For example, one end (or one portion) of the third connection electrode 180 can be connected to the first thin film transistor 200, and the other end (or another portion) of the third connection electrode 180 can be connected to the light emitting element layer 500.

An anode electrode 510 can be disposed on the planarization layer 170. The anode electrode 510 can be electrically connected to the first drain electrode 270 through a hole of the planarization layer 170. Alternatively, the anode electrode 510 can be electrically connected to the first drain electrode 270 through the third connection electrode 180.

The anode electrode 510 can be made of a conductive material which supplies holes to a light emitting layer 530 and has a high work function.

When the display device 100 is a top emission type, the anode electrode 510 can be disposed using an opaque conductive material as a reflective electrode which reflects light. For example, the anode electrode 510 can be formed of at least one among silver (Ag), aluminum (Al), gold (Au), molybdenum (Mo), tungsten (W), chromium (Cr) and alloys thereof. For example, the anode electrode 510 can be made of a three-layered structure of silver (Ag)/lead (Pd)/copper (Cu), but is not limited thereto.

When the display device 100 is a bottom emission type, the anode electrode 510 can be disposed using a transparent conductive material which transmits light. For example, the anode electrode 510 can be formed of at least one of indium tin oxide (ITO) and indium zinc oxide (IZO).

A bank layer 520 can be disposed on the anode electrode 510 and the planarization layer 170. The bank layer 520 can distinguish a plurality of subpixels SP, minimize or reduce a light blurring phenomenon, and prevent or reduce color mixing occurring at various viewing angles.

The bank layer 520 can have a bank hole which exposes the anode electrode 510 corresponding to a light emitting area.

The bank layer 520 can be made of at least one material among inorganic insulating material such as silicon nitride (SiNx) or silicon oxide (SiOx) or organic insulating materials such as benzocyclobutene (BCB), acrylic resin, epoxy resin, phenolic resin, polyamide resin and polyimide resin, but is not limited thereto.

A spacer can be additionally disposed on the bank layer 520. The spacer can buffer an empty space between the substrate 110 formed with the light emitting element layer 500 and an upper substrate, thereby minimizing or reducing damage to the display device 100 by impact from the outside. The spacer can be formed of the same material as the bank layer 520 and can be formed simultaneously with the bank layer 520, but is not limited thereto.

The light emitting layer 530 can be disposed on the anode electrode 510 and the bank layer 520. The light emitting layer 530 can include one among a red organic light emitting layer, a green organic light emitting layer, a blue organic light emitting layer and a white organic light emitting layer in order to emit light of a specific color. When the light emitting layer 530 includes a white organic light emitting layer, a color filter for converting white light from the white organic light emitting layer into light of a different color can be disposed on the light emitting element layer 500. In addition to an organic light emitting layer, the light emitting layer 530 can further include a hole injection layer, a hole transport layer, an electron transport layer and an electron injection layer, but is not limited thereto.

A cathode electrode 540 can be disposed on the light emitting layer 530. The cathode electrode 540 can be made of a conductive material which supplies electrons to the light emitting layer 530 and has a low work function.

When the display device 100 is a top emission type, the cathode electrode 540 can be disposed using a transparent conductive material which transmits light. For example, the cathode electrode 540 can be formed of at least one of indium tin oxide (ITO) and indium zinc oxide (IZO), but is not limited thereto.

In addition, the cathode electrode 540 can be disposed using a translucent conductive material which transmits light. For example, the cathode electrode 540 can be formed of at least one among alloys such as LiF/Al, CsF/Al, Mg:Ag, Ca/Ag, Ca:Ag, LiF/Mg:Ag, LiF/Ca/Ag and LiF/Ca:Ag, but is not limited thereto.

When the display device 100 is a bottom emission type, the cathode electrode 540 can be disposed using an opaque conductive material as a reflective electrode which reflects light. For example, the cathode electrode 540 can be formed of at least one among silver (Ag), aluminum (Al), gold (Au), molybdenum (Mo), tungsten (W), chromium (Cr) and alloys thereof.

A protective layer 600 can be disposed on the cathode electrode 540 of the light emitting element layer 500. The protective layer 600 can protect the light emitting element layer 500 from external moisture, oxygen, or foreign matter. For example, in order to prevent or reduce oxidation of a light emitting material and an electrode material, the protective layer 600 can prevent or reduce penetration of oxygen and moisture from the outside.

The protective layer 600 can be made of a transparent material to transmit light emitted from the light emitting layer 530.

The protective layer 600 can include a first protective layer 610, a second protective layer 620 and a third protective layer 630 which block or reduce penetration of moisture or oxygen. The first protective layer 610, the second protective layer 620 and the third protective layer 630 can have an alternately stacked structure. The protective layer 600 can be made of a transparent material to transmit light emitted from the light emitting layer 530.

The first protective layer 610 and the third protective layer 630 can be made of at least one inorganic material among silicon nitride (SiNx), silicon oxide (SiOx) and aluminum oxide (AlyOz), but are not limited thereto. The first protective layer 610 and the third protective layer 630 can be formed using a vacuum deposition method such as chemical vapor deposition (CVD) or atomic layer deposition (ALD), but are not limited thereto.

The second protective layer 620 can cover foreign substances or particles that can occur in a manufacturing process. In addition, the second protective layer 620 can planarize the surface of the first protective layer 610. For example, the second protective layer 620 can be a particle cover layer, but is not limited to the term.

The second protective layer 620 can be an organic material, for example, a polymer based on silicon oxycarbon (SiOCz), epoxy, polyimide, polyethylene or acrylate, but is not limited thereto.

The second protective layer 620 can be made of a heat-curable material or a photo-curable material that is cured by heat or light.

It is to be noted that the specific structure of the display device shown in FIGS. 3-4 is provided by way of example only, and the present disclosure is not limited thereto. For example, one or more layers shown in FIG. 4 can be changed in position, omitted, or replaced by other elements, when necessary.

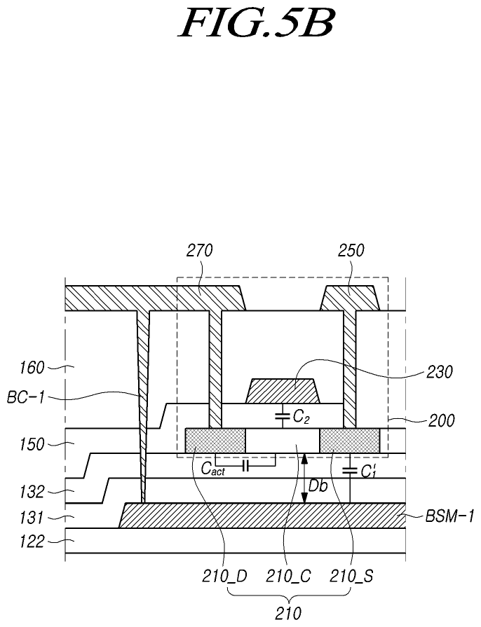

FIG. 5A is a cross-sectional view illustrating a first thin film transistor illustrated in the display device in accordance with the example embodiments of the present disclosure of FIG. 4, and FIG. 5B is a cross-sectional view illustrating a first thin film transistor of a comparison example.

When the semiconductor pattern of a driving thin film transistor includes an oxide semiconductor, because a current fluctuation value with respect to a unit voltage fluctuation value is large due to the material characteristics of the oxide semiconductor, some defects can occur in a low grayscale area where precise current control is needed. Therefore, in the embodiments of the present disclosure, a driving thin film transistor in which a current fluctuation value with respect to a fluctuation value of a voltage applied to a gate electrode in a semiconductor pattern is relatively insensitive can be provided.

Referring to the embodiment of FIG. 5A, the first light shield layer BSM-1 and the doped area 141 of the silicon layer 140 are electrically connected through the first connection electrode BC-1. Therefore, when a specific voltage is applied to the first light shield layer BSM-1, the first light shield layer BSM-1 and the doped area 141 form an equipotential. A voltage applied to the first light shield layer BSM-1 can be different from a voltage applied to the first gate electrode 230. For example, the first light shield layer BSM-1 can be electrically connected to the first drain electrode 270. The first light shield layer BSM-1 can be applied with a constant voltage regardless of the voltage applied to the first gate electrode 230. Accordingly, a parasitic capacitance having a first capacitance C₁ can be formed between the doped area 141 forming an equipotential with the first light shield layer BSM-1 and the first semiconductor pattern 210. A parasitic capacitance having a second capacitance C₂ can be formed between the first semiconductor pattern 210 and the first gate electrode 230.

Referring to the comparison example of FIG. 5B, when a constant voltage is applied to the first light shield layer BSM-1 regardless of a voltage applied to the first gate electrode 230, a parasitic capacitance having a first capacitance C₁′ can be formed between the first light shield layer BSM-1 and the first semiconductor patterns 210. A parasitic capacitance having a second capacitance C₂ can be formed between the first semiconductor pattern 210 and the first gate electrode 230.

As the first source area 210_S and the first drain area 210_D being the ends of the first semiconductor pattern 210 are doped with impurities, when a voltage is applied to a semiconductor pattern, a parasitic capacitance having a third capacitance C_{ACT} can be formed in the first semiconductor pattern 210.

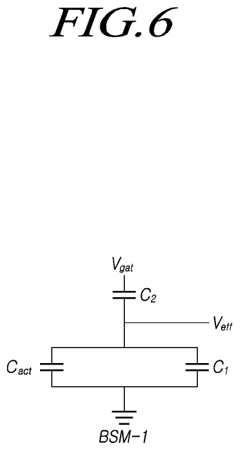

Referring to FIG. 6, in the display device in accordance with the example embodiments of the present disclosure, the amount of change in effective gate voltage that affects a driving current applied to the light emitting element layer 500 can be determined by the following equation (Equation 1).

$$Δ {V}_{eff} = \frac{C 2}{C 2 + {C}_{ACT} + C 1} \times Δ {V}_{GAT} \qquad [ Equation 1 ]$$

Here, ΔV_{eff} means an amount of change in effective gate voltage (or an effective voltage), and can be a voltage actually applied to the channel of the first semiconductor pattern 210. Further, ΔV_{GAT} means an amount of change in voltage applied to the first gate electrode 230, and C1 and C2 are the same as the first and second capacitances C₁ and C₂ respectively.

Referring to [Equation 1], by controlling the first parasitic capacitance C₁ or C₁′ formed between the doped area 141 or the first light shield layer BSM-1 and the first semiconductor pattern 210, it is possible to exert an influence on the generation of a driving current. For example, since the effective voltage ΔV_{eff} applied to the channel of the first semiconductor pattern 210 is inversely proportional to the first parasitic capacitance C₁ or C₁′, an effective voltage applied to an oxide semiconductor pattern can be adjusted by adjusting the first parasitic capacitance C₁ or C₁′ according to Equation 2.

$$C = Q / V = {ε}_{o} A / d \qquad [ Equation 2 ]$$

Here, ε₀: dielectric constant, A: area, d: electrode distance.

Referring to [Equation 2], a capacitance increases as the distance between electrodes decreases. Therefore, when the magnitude of the parasitic capacitance C₁′ is increased by disposing the first light shield layer BSM-1 close to the first semiconductor pattern 210 in the comparison example, the amount of change ΔV_{eff} in voltage value applied to the first semiconductor pattern 210 can be reduced.

A decrease in the amount of change Δ in the value of effective current flowing through the first semiconductor pattern 210 can mean that the control range of the first thin film transistor 200 to be controlled through the amount of change ΔV_{GAT} of voltage applied to the first gate electrode 230 is widened.

Therefore, since a vertical distance Da between the first semiconductor pattern 210 of the first thin film transistor 200 and the doped area 141 in accordance with the example embodiments of the present disclosure illustrated in FIG. 5A can be formed to be smaller than a vertical distance Db between the first semiconductor pattern 210 of the first thin film transistor 200 and the first light shield layer BSM-1 in accordance with the comparison example illustrated in FIG. 5B, a range through which the first thin film transistor 200 in accordance with the example embodiments of the present disclosure controls a grayscale can be widened. As a result, because it is possible to precisely control a light emitting element layer even at a low grayscale, the issue of screen stains which can frequently occur at a low grayscale can be addressed effectively.

For reference, the S-factor is commonly referred to as a “sub-threshold slope”, and can refer to a reciprocal value of the amount of change in current according to the amount of change in gate voltage in the on/off transition region of a thin film transistor. Since a large S-factor means that the slope of the characteristic graph (I-V) of the drain current with respect to the gate voltage is small, the threshold voltage is reached for a relatively long time period to make sufficient grayscale expression possible.

According to the embodiments of the present disclosure, it is possible to provide a display device capable of realizing a wide range of grayscale representation and a fast on-off operation by improving an S-factor by disposing a doped silicon layer under the semiconductor pattern of a specific thin film transistor.

According to the embodiments of the present disclosure, it is possible to provide a display device capable of realizing a wide range of grayscale representation and a fast on-off operation by improving an S-factor by disposing a doped silicon layer under the semiconductor pattern of a thin film transistor including an oxide semiconductor.

A brief description of the embodiments of the present disclosure described above is as follows.

Embodiments of the present disclosure can provide a display device including a light shield layer disposed on a substrate, a first buffer layer disposed on the light shield layer, a silicon layer disposed on the first buffer layer and including an undoped area and a doped area, a second buffer layer disposed on the silicon layer and a thin film transistor disposed on the second buffer layer, wherein the doped area is disposed at a position overlapping with the light shield layer.

In the display device in accordance with the example embodiments of the present disclosure, the light shield layer can be formed as a single layer or a multi-layer made of any one of molybdenum (Mo), copper (Cu), titanium (Ti), aluminum (Al), chromium (Cr), gold (Au), nickel (Ni), neodymium (Nd) and tungsten (W) or an alloy thereof.

In the display device in accordance with the example embodiments of the present disclosure, the light shield layer can include titanium (Ti).

In the display device in accordance with the example embodiments of the present disclosure, the thin film transistor can include a semiconductor pattern, a gate electrode, a source electrode and a drain electrode, and the doped area and the light shield layer can be electrically connected to the source electrode or the drain electrode through a connection electrode.

In the display device in accordance with the example embodiments of the present disclosure, the semiconductor pattern can overlap with the doped area and the light shield layer.

In the display device in accordance with the example embodiments of the present disclosure, an area of the semiconductor pattern can be equal to or smaller than an area of the light shield layer or an area of the doped area.

In the display device in accordance with the example embodiments of the present disclosure, an area of the doped area can be equal to or larger than an area of the light shield layer.

In the display device in accordance with the example embodiments of the present disclosure, the silicon layer can include any one selected from the group including monocrystalline silicon, polycrystalline silicon, and amorphous silicon.

In the display device in accordance with the example embodiments of the present disclosure, the silicon layer can be disposed to cover the entire surface of the first buffer layer.

In the display device in accordance with the example embodiments of the present disclosure, the doped area can be doped with an n-type impurity or a p-type impurity.

In the display device in accordance with the example embodiments of the present disclosure, the display device can include a capacitor including a first capacitor electrode and a second capacitor electrode, the first capacitor electrode can be disposed at the same layer as the light shield layer, and the second capacitor electrode can be disposed at the same layer as the gate electrode.

In the display device in accordance with the example embodiments of the present disclosure, the undoped area of the silicon layer can be disposed between the first capacitor electrode and the second capacitor electrode.

In the display device in accordance with the example embodiments of the present disclosure, the second capacitor electrode can be electrically connected to the semiconductor pattern through the source electrode or the drain electrode.

In the display device in accordance with the example embodiments of the present disclosure, the semiconductor pattern can include an oxide semiconductor.

Embodiments of the present disclosure can provide a display device including a first light shield layer disposed on a substrate, a first buffer layer disposed on the first light shield layer, a silicon layer disposed on the first buffer layer and including an undoped area and a doped area, a second buffer layer disposed on the silicon layer, and first and second thin film transistors disposed on the second buffer layer, wherein the doped area is disposed at a position overlapping with the first light shield layer.

In the display device in accordance with the example embodiments of the present disclosure, the first thin film transistor can include a first semiconductor pattern, a first gate electrode, a first source electrode and a first drain electrode, the second thin film transistor can include a second semiconductor pattern, a second gate electrode, a second source electrode and a second drain electrode, and the doped area and the first light shield layer can be electrically connected to the first source electrode or the first drain electrode through a first connection electrode.

In the display device in accordance with the example embodiments of the present disclosure, the display device can further include a light emitting element layer electrically connected to the first thin film transistor, wherein the first gate electrode of the first thin film transistor can be electrically connected to the second source electrode or the second drain electrode of the second thin film transistor.

In the display device in accordance with the example embodiments of the present disclosure, the first semiconductor pattern can overlap with the doped area and the first light shield layer.

In the display device in accordance with the example embodiments of the present disclosure, an area of the doped area can be equal to or larger than an area of the first light shield layer.

In the display device in accordance with the example embodiments of the present disclosure, the silicon layer can include any one selected from the group including monocrystalline silicon, polycrystalline silicon, and amorphous silicon.

In the display device in accordance with the example embodiments of the present disclosure, the silicon layer can be disposed to cover the entire surface of the first buffer layer.

In the display device in accordance with the example embodiments of the present disclosure, the doped area can be doped with an n-type impurity or a p-type impurity.

In the display device in accordance with the example embodiments of the present disclosure, the display device can include a capacitor including a first capacitor electrode and a second capacitor electrode, the first capacitor electrode can be disposed at the same layer as the first light shield layer, and the second capacitor electrode can be disposed at the same layer as the first gate electrode.

In the display device in accordance with the example embodiments of the present disclosure, the display device can further include a second light shield layer disposed below the second semiconductor pattern, wherein the undoped area of the silicon layer is disposed between the second light shield layer and the second semiconductor pattern and between the first capacitor electrode and the capacitor electrode.

In the display device in accordance with the example embodiments of the present disclosure, the second capacitor electrode can be electrically connected to the first semiconductor pattern through the first source electrode or the first drain electrode.

In the display device in accordance with the example embodiments of the present disclosure, the first semiconductor pattern can include an oxide semiconductor, and the second semiconductor pattern can be an oxide semiconductor, a polycrystalline silicon semiconductor or an amorphous silicon semiconductor.

According to the embodiments of the present disclosure, it is possible to provide a display device capable of realizing a wide range of grayscale representation and a fast on-off operation by adjusting the S-factor of a specific thin film transistor.

According to the embodiments of the present disclosure, it is possible to provide a display device capable of realizing a wide range of grayscale representation and a fast on-off operation by improving an S-factor by disposing a doped silicon layer under the semiconductor pattern of a specific thin film transistor.

According to the embodiments of the present disclosure, it is possible to provide a display device capable of realizing a wide range of grayscale representation and a fast on-off operation by improving an S-factor by disposing a doped silicon layer under the semiconductor pattern of a thin film transistor including an oxide semiconductor.

According to the embodiments of the present disclosure, it is possible to provide a display device capable of blocking or reducing upwardly introducing light by disposing a silicon layer under the entire surface of the semiconductor patterns of a plurality of thin film transistors.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the technical idea and scope of the present disclosure. The above description and the accompanying drawings provide an example of the technical idea of the present disclosure for illustrative purposes only. For example, the disclosed embodiments are intended to illustrate the scope of the technical idea of the present disclosure.

What is claimed is:

1. A display device comprising:
a light shield layer disposed on a substrate;
a first buffer layer disposed on the light shield layer;
a silicon layer disposed on the first buffer layer, and including an undoped area and a doped area;
a second buffer layer disposed on the silicon layer; and
a thin film transistor disposed on the second buffer layer,
wherein the doped area of the silicon layer is disposed at a position overlapping with the light shield layer.

2. The display device of claim 1, wherein the light shield layer is formed as a single layer or a multi-layer made of any one of molybdenum (Mo), copper (Cu), titanium (Ti), aluminum (Al), chromium (Cr), gold (Au), nickel (Ni), neodymium (Nd) and tungsten (W) or an alloy thereof.

3. The display device of claim 2, wherein the light shield layer includes titanium (Ti).

4. The display device of claim 1, wherein
the thin film transistor includes a semiconductor pattern, a gate electrode, a source electrode and a drain electrode, and
the doped area and the light shield layer are electrically connected to the source electrode or the drain electrode through a connection electrode.

5. The display device of claim 4, wherein the semiconductor pattern overlaps with the doped area and the light shield layer.

6. The display device of claim 5, wherein a size of an area of the semiconductor pattern is equal to or smaller than a size of an area of the light shield layer or a size of an area of the doped area.

7. The display device of claim 1, wherein a size of an area of the doped area is equal to or larger than a size of an area of the light shield layer.

8. The display device of claim 1, wherein the silicon layer includes any one selected from a group including monocrystalline silicon, polycrystalline silicon, and amorphous silicon.

9. The display device of claim 1, wherein the silicon layer is disposed to cover an entire surface of the first buffer layer.

10. The display device of claim 1, wherein the doped area of the silicon layer is doped with an n-type impurity or a p-type impurity.

11. The display device of claim 4, further comprising: a capacitor including a first capacitor electrode and a second capacitor electrode,
wherein the first capacitor electrode is disposed at a same layer as the light shield layer, and the second capacitor electrode is disposed at a same layer as the gate electrode.

12. The display device of claim 11, wherein the undoped area of the silicon layer is disposed between the first capacitor electrode and the second capacitor electrode.

13. The display device of claim 11, wherein the second capacitor electrode is electrically connected to the semiconductor pattern through the source electrode or the drain electrode.

14. The display device of claim 4, wherein the semiconductor pattern includes an oxide semiconductor.

15. A display device comprising:
a first light shield layer disposed on a substrate;
a first buffer layer disposed on the first light shield layer;
a silicon layer disposed on the first buffer layer, and including an undoped area and a doped area;
a second buffer layer disposed on the silicon layer; and
first and second thin film transistors disposed on the second buffer layer,
wherein the doped area of the silicon layer is disposed at a position overlapping with the first light shield layer.

16. The display device of claim 15, wherein
the first thin film transistor includes a first semiconductor pattern, a first gate electrode, a first source electrode and a first drain electrode,
the second thin film transistor includes a second semiconductor pattern, a second gate electrode, a second source electrode and a second drain electrode, and
the doped area and the first light shield layer are electrically connected to the first source electrode or the first drain electrode through a first connection electrode.

17. The display device of claim 16, further comprising:
a light emitting element layer electrically connected to the first thin film transistor,
wherein the first gate electrode of the first thin film transistor is electrically connected to the second source electrode or the second drain electrode of the second thin film transistor.

18. The display device of claim 16, wherein the first semiconductor pattern overlaps with the doped area and the first light shield layer.

19. The display device of claim 15, wherein a size of an area of the doped area is equal to or larger than a size of an area of the first light shield layer.

20. The display device of claim 15, wherein the silicon layer includes any one selected from a group including monocrystalline silicon, polycrystalline silicon, and amorphous silicon.

21. The display device of claim 15, wherein the silicon layer is disposed to cover an entire surface of the first buffer layer.

22. The display device of claim 15, wherein the doped area of the silicon layer is doped with an n-type impurity or a p-type impurity.

23. The display device of claim 16, further comprising:
a capacitor including a first capacitor electrode and a second capacitor electrode,
wherein the first capacitor electrode is disposed at a same layer as the first light shield layer, and the second capacitor electrode is disposed at a same layer as the first gate electrode.

24. The display device of claim 23, further comprising:
a second light shield layer disposed below the second semiconductor pattern,
wherein the undoped area of the silicon layer is disposed between the second light shield layer and the second semiconductor pattern and between the first capacitor electrode and the second capacitor electrode.

25. The display device of claim 23, wherein the second capacitor electrode is electrically connected to the first semiconductor pattern through the first source electrode or the first drain electrode.

26. The display device of claim 23, wherein
the first semiconductor pattern includes an oxide semiconductor, and
the second semiconductor pattern includes an oxide semiconductor, a polycrystalline silicon semiconductor or an amorphous silicon semiconductor.
